(19) United States
(12) Patent Application Publication
(10) Pub. No.: US 2002/0036511 A1
(43) Pub. Date: Mar. 28, 2002

(54) Printed circuit board and method of manufacturing the same

(76) Inventor: Hideaki Kawai, Tokyo (JP)

Correspondence Address: FLYNN, THIEL, BOUTELL & TANIS, P.C., 2026 Rambling Road, Kalamazoo, MI, 49008-1699, US

(21) Appl. No.: 09/963,017

(22) Filed: Sep. 25, 2001

(30) Foreign Application Priority Data
Sep. 27, 2000 (JP) 2000-294800

(51) Int. Cl. G01R 31/02

(52) U.S. Cl. 324/755

(57) ABSTRACT

There is provided a printed circuit board which can prevent air leakage from through holes, can eliminate a possibility of the occurrence of a short of patterns caused by soldering, and can be manufactured at low cost in a short time while solder does not interfere with a device fixing mechanism part, and another object of the invention is to provide a method of manufacturing the printed circuit board. The printed circuit board comprises a plate-like body section, through holes which are formed by penetrating front and back faces of the body section, a device under test being arranged on one region bordering on the body section, a semiconductor test unit for testing the device under test, wherein one region is set at prescribed temperature conditions in a state where the semiconductor test unit is electrically connected to the device under test from the other face of the body section via the through holes, thereby testing the device under test, wherein block members each made of an insulating material is provided on the body section so as to block the through holes, thereby preventing a gas from circulating between the front and back faces of the body section via the through holes.

### BACKGROUND OF THE INVENTION

1. Field of the Invention

The invention relates to a printed circuit board (referred to as a test board and the like) which is used for testing a device under test, and a method of manufacturing the printed circuit board.

2. Related Art

A method of testing a device under test 6 such as an IC (integrated circuit) connected to a semiconductor test unit (IC tester) 4 via a test board (printed circuit board) 1 is described with reference to FIG. 1. The semiconductor test unit 4 for testing the device under test 6 is first electrically connected to the test board 1 via connectors 3 connected to tip ends of a signal cable 5 extended from the semiconductor test unit 4. A surface mounting type connector is used for the convenience of a mounting space and mounting operation on the test board 1. For this reason, many through holes 8 for connecting between the connectors 3 and inner layer patterns are formed on the test board 1, by penetrating front and back faces of the test board 1. Further, the connectors 3 are soldered onto the lower surface (back face) of the test board 1 so as to be positioned at intervals between the through holes 8. As a result, the connectors 3 are electrically connected to the inner layer patterns and the upper surface (front face) of the test board 1 via the through holes 8. Further, a plurality of devices under test 6 are attached onto the front face of the test board 1 via a device fixing mechanism part 7 for fixing the devices under test 6 in a state where they are electrically connected to the connectors 3. Accordingly, each device under test 6 is rendered in a state to be tested while it is electrically connected to the semiconductor test unit 4 via the device fixing mechanism part 7, the through holes 8, the connectors 3 and the signal cable 5.

Since characteristics of each device under test 6 are varied depending on temperature conditions, the device under test 6 is generally disposed within a temperature setting region 2 so that it is maintained at prescribed temperature conditions (e. g., at a high temperature) while each device under test 6 is tested by the semiconductor test unit 4. For example, as shown in FIG. 1, if the test board 1 functions as a partition wall for partitioning the inside and outside of the temperature setting region 2, there occurs a difference in temperature between the front and back faces of the test board 1. In this case, since air passes through the inside and outside of the temperature setting region 2, namely, air leaks therebetween, there is a possibility that the inside of the temperature setting region 2 is not maintained at a desired temperature. This is particularly noticeable when a test time becomes long.

The through holes 8 have been conventionally blocked by solder 9, as shown in FIG. 3, so as to prevent air leakage via the through holes 8. Various parts are mounted on the back face of the test board 1, which impedes soldering thereon, and hence soldering is effected from the front face of the test board 1.

However, it has been necessary in the prior art that many through holes 8 are filled with solder 9 when assembling the test board 1, resulting in the requirement of many steps, and also there is a possibility of the occurrence of a short of patterns owing to the conductive solder 9. Further, as shown in FIG. 3, it has been necessary to scrape off protrusions 9a which are formed when some solder 9 is protruded from the through holes 8, for example, by a file and the like at the portion where the protrusions 9a interfere with the device fixing mechanism part 7, which has been very troublesome.

### SUMMARY OF THE INVENTION

An object of the invention is to provide a printed circuit board which can prevent air leakage from through holes, can eliminate a possibility of the occurrence of a short of patterns caused by soldering, and can be manufactured at low cost in a short time while solder does not interfere with a device fixing mechanism part, and another object of the invention is to provide a method of manufacturing the printed circuit board.

To achieve the above object, a printed circuit board (e.g. test board) 1 according to the first aspect of the invention comprises, e.g., as shown in FIG. 1 and 2, a plate-like body section 1a, through holes 8 which are formed by penetrating front and back faces of the body section 1a, a device under test (hereinafter referred to as a DUT) 6 being arranged on one region (temperature setting region) 2 bordering on the body section 1a, a β (semiconductor test unit) 4 for testing the DUT 6, wherein one region is set at prescribed temperature conditions in a state where the test unit 4 is electrically connected to the DUT 6 from the other face of the body section 1a via the through holes 8, thereby testing the DUT 6, wherein block members 10 each made of an insulating material are provided on the body section 1a so as to block the through holes 8, thereby preventing a gas from passing or circulating between the front and back faces of the body section 1a via the through holes 8.

The DUT 6 is e.g., a semiconductor device. A prescribed temperature is defined to include all the desired setting temperatures (e.g., including a temperature which is time-varied in a prescribed cycle) as well as a constant temperature.

According to the first aspect of the invention, since a gas can be prevented from passing through the front and back faces of the body section 1a via the through holes 8, the region where the DUT 6 is disposed can be maintained at a prescribed temperature. Further, since each block member 10 is made of an insulating material, it is possible to prevent the occurrence of short of patterns, namely, prevent the occurrence of a short-circuit between the patterns of the printed circuit board owing to the block member 10.

A method of manufacturing a printed circuit board comprising e.g., as shown FIGS. 1 and 2, a plate-like body section 1a, through holes 8 which are formed by penetrating front and back faces of the body section 1a, a device under test (hereinafter referred to as DUT) 6 being arranged on one region (temperature setting region) 2 bordering on the body section 1a, a test unit (semiconductor test unit) 4 for testing the DUT 6, wherein one region is set at prescribed temperature conditions in a state where the semiconductor test unit 4 is electrically connected to the DUT 6 from the other face of the body section 1a via the through holes 8, thereby testing the DUT 6, wherein block members 10 each made of an insulating material are provided on the body section 1a so as to block the through holes 8, thereby preventing a gas from circulating between the front and back faces of the body section 1a via the through holes 8, said method comprising fixing the block members 10 to the body section so as to block the through holes 8, while the block members 10 are forced to move to and pass through hole sections defined in mask means at portions corresponding to the through holes 8 in a state where the mask means is overlaid on the printed circuit board.

The mask means is a film-like member or a thin plate-like member each having hole sections which are defined at the portions corresponding to the through holes 8. Further, the block members may be made of an insulating material or a conductive material.

According to the second aspect of the invention, the block members, which are forced to move to and pass through the hole sections of the mask means in a state where the mask means is overlaid on the printed circuit board, are fixed to the body section in a state where they block the through holes 8 so that the through holes 8 of the printed circuit board can be blocked with ease. Accordingly, manufacturing time for manufacturing the printed circuit board of the invention can be sharply reduced compared with a case where the through holes 8 have been conventionally blocked by soldering.

According to the third aspect of the invention, in the method of manufacturing the printed circuit board 1 in the second aspect of the invention, each block member is formed of an insulating member.

According to the third aspect of the invention, since the block members are formed of an insulating member, there does not occur a short of patterns owing to the block members.

According to the fourth aspect of the invention, in the method of manufacturing the printed circuit board 1 in the third aspect of the invention, resist ink is used as the insulating material.

According to the fourth aspect of the invention, since resist ink is used as the insulating material, the blocking members each having a very thin thickness can be easily formed.

According to the fifth aspect of the invention, in the method of manufacturing the printed circuit board in any of the second to fourth aspects of the invention, a part (e.g. a device fixing mechanism part) 7 is provided on either face of front and back faces of the body section 1a so as to cover the through holes 8, and the block members 10 are fixed to the body section from the other face of the front and back faces of the body section 1a.

According to the fifth aspect of the invention, since the block members 10 are fixed to the body section from the other face of the front and back faces of the body section 1a, the block members 10 are prevented from being positioned at one face of the front and back faces of the body section 1a. Accordingly, the block members 10 do not become a bar to the provision of parts or devices on the printed circuit board in a state to cover the through holes 8.

### BRIEF DESCRIPTION OF THE DRAWINGS

FIG. 1 is a view for explaining a method of testing a DUT by use of a printed circuit board.

FIG. 2 is an enlarged sectional view of the printed circuit board of the invention.

FIG. 3 is an enlarged sectional view of a conventional printed circuit board.

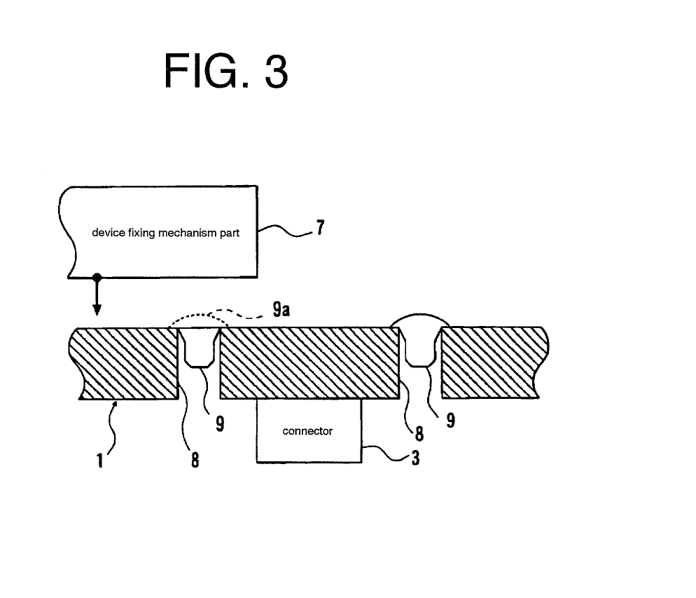

### PREFERRED EMBODIMENT OF THE INVENTION

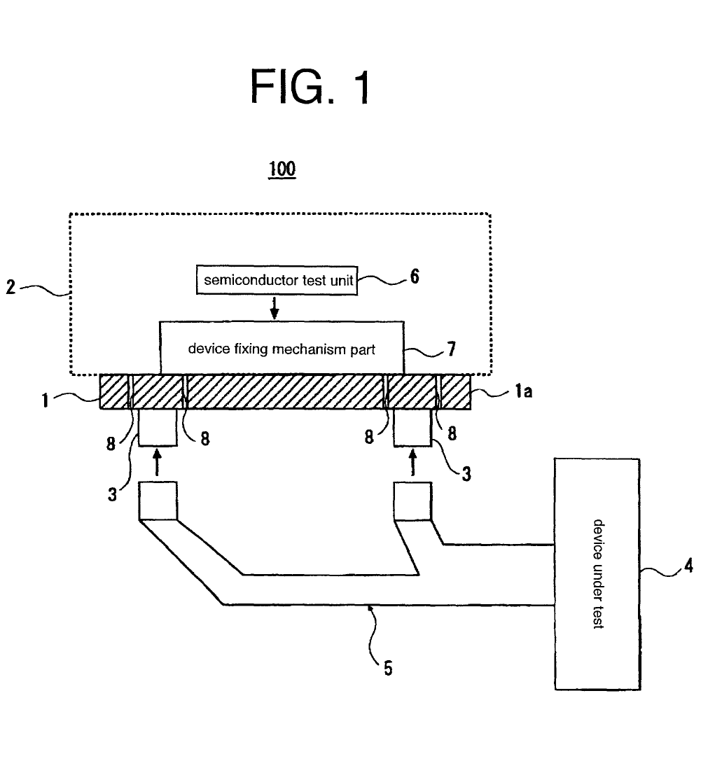

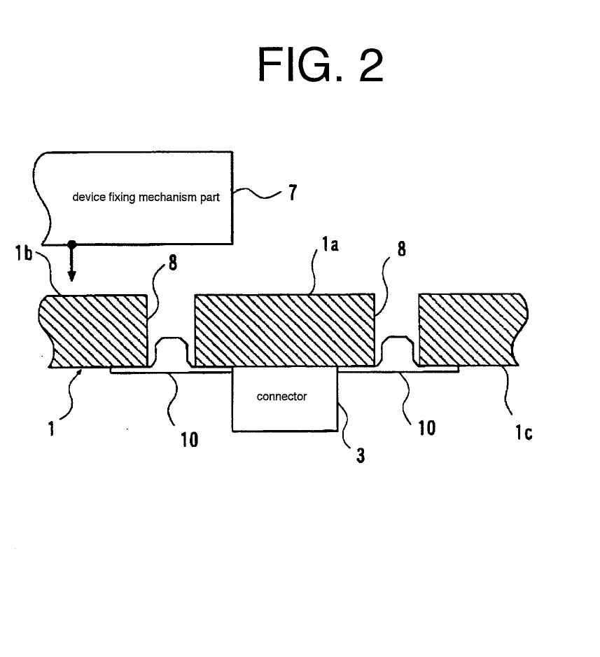

A preferred embodiment of the invention is now described with reference to the attached drawings. A test system 100 for testing a device DUT 6 is first described with reference to FIG. 1. The test system 100 comprises a semiconductor test unit 4 for applying a test signal and the like to the DUT 6, a signal cable 5, a test board (printed circuit board) 1 connected to the semiconductor test unit 4 via connectors 3 provided at tip ends of the signal cable 5, an autohandler (not shown), a temperature setting region (one region) 2 inside a constant temperature bath (not shown) provided in the autohandler. Further, as shown in FIGS. 1 and 2, the test board 1 comprises a plate-like body section 1a and a plurality of through holes 8 formed by penetrating the front and back faces of the body section 1a. A device fixing mechanism part 7 is attached onto the test board 1 for setting the DUT 6 onto the test board 1. Many test boards 1 are mounted on a test head (IC tester), not shown, and a test signal is applied from the semiconductor test unit 4 to the DUT 6 in a state where the test head is connected to the autohandler so as to test the DUT 6. At the time of testing the DUT 6, although the DUT 6 disposed inside the temperature setting region 2 is maintained at prescribed temperature conditions, the body section 1a of the test board 1 serves as a partition wall between the inside and outside of the temperature setting region 2, so that there occurs a difference in temperature between the front and back faces of the test board 1.

Accordingly, in a state where the through holes 8 of the test board 1 are opened, air (gas) passes through the front and back faces of the test board 1 via the through holes 8, so that the temperature setting region 2 can not be maintained at prescribed temperature conditions. To solve this problem, the test board 1 provided with the block members 10 for blocking the through holes 8 is used by the invention in the following manner.

In order to provide the block members 10 for blocking the through holes 8 of the test board 1, means having hole sections defined at the portions corresponding to the through holes 8 of the test board 1, e.g. a film-like or thin plate like mask means (not shown) is used. When the block members 10 are provided, the mask means is rendered in a state where it is overlaid on the body section 1a of the test board 1 so as to align the hole sections of the mask means with the through holes 8. Thereafter, the block members 10 are applied onto the mask means from above, i.e. from the upper side of the mask means, the block members 10 are forced to move to and pass through the hole sections of the mask means, thereby fixing the block members 10 to the body section in a state to block the through holes 8. For a material of each block member 10, e.g., resist ink made of an insulating material is preferably used.

Since the device fixing mechanism part 7 is attached onto a front face 1b of the test board 1 so as to cover a part of openings of the through holes 8 as shown in FIG. 2, it is preferable that the block members 10 are not provided at the front face 1b. Accordingly, the block members 10 are applied onto the mask means in a state where the mask means is overlaid on a back face 1c of the test board 1, so that each block member 10 is fixed to the body section 1a from the back face 1c. As a result, since each block member 10 is fixed to the back face 1c of the test board 1 as shown in Fig.2, each block member 10 does not become a bar when the device fixing mechanism part 7 is attached onto the front face 1b of the test board 1.

According to the preferred embodiment of the invention, since the test board 1 having the through holes 8 which are blocked by the block members 10 is used, it is possible to prevent a gas from passing through the front and back faces of the body section 1a via the through holes 8. Accordingly, the temperature setting region 2 where the DUT 6 is disposed can be maintained at a prescribed temperature.

In a state where the mask means is overlaid on the test board 1, the block members 10, which are forced to move to and pass through the hole sections of the mask means, are fixed to the body section 1a in a state where they block the through holes 8, thereby easily blocking the through holes 8. Accordingly, manufacturing time for manufacturing the printed circuit board can be sharply reduced, thereby reducing a manufacturing cost compared with a conventional case where individual through holes 8 are soldered.

Since the block members1O are made of an insulating material, there does not occur a short of patterns owing to the block members 10. Particularly, since resist ink is used as the insulating material, it is possible to easily form the block members 10 each having a very think thickness. Accordingly, in time of need, even if there is a necessity of providing parts or devices on the test board 1 in a state to cover the block member 10, there is a low possibility that the block members 10 impedes the provision of the devices. Since the block members 10 are fixed to the body section 1a from the back face 1c of the test board 1, it is possible to prevent the block members 10 from being positioned at the front face 1b of the body section 1a. Accordingly, the block members 10 do not become a bar, for example, when the device fixing mechanism part 7 and the like are provided on the front face 1b of the test board 1 in a state to cover the through holes 8.

According to the preferred embodiment, although the insulating material (particularly, resist ink) is used as each block member 10, the invention is not limited thereto. That is, a block member made of a material other than the insulating material is forced to move to and pass through the hole sections of the mask means in a state where the block member 10 is overlaid on the body section 1a, thereby fixing the block member to the body section 1a in a state where the through holes 8 are blocked by the block member.

According to the printed circuit board of the first aspect of the invention, since the block members 10 are made of an insulating material, there does not occur a short of patterns owing to the block members.

According to the method of manufacturing a printed circuit board of the second aspect of the invention, the through holes of the printed circuit board can be easily blocked, manufacturing time for manufacturing the printed circuit board can be sharply reduced compared with a conventional case where individual through holes are soldered.

According to the method of manufacturing a printed circuit board of the third aspect of the invention, since the block members are made of an insulating material, there does not occur a short of patterns owing to the block members.

According to the method of manufacturing a printed circuit board of the fourth aspect of the invention, since resist ink is used as the insulating material, block members each having a thin thickness can be easily formed.

According to the method of manufacturing a printed circuit board of the fifth aspect of the invention, the block members can be fixed to the body section from the other face of the body section, it is possible to prevent the block members from being positioned at one face of the body section. Accordingly, when parts are mounted on one face of the body section in a state to cover the through holes, the block members do not become a bar.

What is claimed is:

1. A printed circuit board comprising a plate-like body section, through holes which are formed by penetrating front and back faces of the body section, a device under test being arranged on one region bordering on the body section, a semiconductor test unit for testing the device under test, wherein one region is set at prescribed temperature conditions in a state where the semiconductor test unit is electrically connected to the device under test from the other face of the body section via the through holes, thereby testing the device under test, wherein block members each made of an insulating material is provided on the body section so as to block the through holes, thereby preventing a gas from circulating between the front and back faces of the body section via the through holes.

2. A method of manufacturing the printed circuit board comprising a plate-like body section, through holes which are formed by penetrating front and back faces of the body section, a device under test being arranged on one region bordering on the body section, a semiconductor test unit for testing the device under test, wherein one region is set at prescribed temperature conditions in a state where the semiconductor test unit is electrically connected to the device under test from the other face of the body section via the through holes, thereby testing the device under test, wherein block members each made of an insulating material is provided on the body section so as to block the through holes, thereby preventing a gas from circulating between the front and back faces of the body section via the through holes, said method comprising fixing the block members to the body section so as to block the through holes, while the block members are forced to move to and pass through hole sections defined in mask means at portions corresponding to the through holes in a state where the mask means is overlaid on the printed circuit board.

3. The method of manufacturing a printed circuit board according to claim 2, wherein each block member is made of an insulating material.

4. The method of manufacturing a printed circuit board according to claim 3, wherein resist ink is used as the insulating material.

5. The method of manufacturing a printed circuit board according to any of claim 2 to 4, wherein s part is provided on either one face of front and back faces of the body section so as to cover the through holes, and each block member is fixed to the body section from either other face of the front and back faces of the body section.
